(19) United States
(12) Patent Application Publication
(10) Pub. No.: US 2009/0255566 A1
(43) Pub. Date: Oct. 15, 2009

(54) SOLAR CELL MODULES

(75) Inventor: Wei-Ko WANG, Taoyuan (TW)

Correspondence Address: Muncy, Geissler, Olds & Lowe, PLLC, P.O. BOX 1364, FAIRFAX, VA, 22038-1364, US

(73) Assignee: VisEra Technologies Company Limited

(21) Appl. No.: 12/102,538

(22) Filed: Apr. 14, 2008

(51) Int. Cl. H01L 31/052

(52) U.S. Cl. 136/246

(57) ABSTRACT

A solar cell module is provided, including a fixture with a solar cell wafer therein and a light-transmitting component formed in the fixture. The solar cell wafer comprises a semiconductor substrate with a plurality of photovoltaic elements formed thereon, wherein the photovoltaic elements are arranged in an array and a plurality of microlenses superimposed over the semiconductor substrate. A pitch between a center of the microlens and a center of the photovoltaic element thereunder increases from a center portion of the array of the photovoltaic elements toward an edge portion of the array of the photovoltaic elements. The light-transmitting component is opposite to the microlenses and partially changes a direction of incident light collected from an ambient from not being perpendicular to a top surface of the microlenses.

### BACKGROUND OF THE INVENTION

1. Field of the Invention

The invention relates to photovoltaic systems and in particular to solar cell modules with optical components for improving light collection efficiency and accuracy of the photovoltaic elements therein.

2. Description of the Related Art

Photovoltaic solar cells for directly converting radiant energy from the sun into electrical energy are well known. The manufacturing of photovoltaic solar cells involves provision of flat semiconductor substrates having a shallow p-n junction adjacent to one surface thereof. Such substrates are often referred to as “solar cell wafers”. Circular or square single crystal silicon substrates and rectangular cast polycrystalline silicon substrates also are commonly used to make solar cells. The solar cell wafers are converted to finished solar cells by providing them with electrical contacts (sometimes referred to as “electrodes”) on both the front and rear sides of the semiconductor substrate, so as to permit recovery of an electrical current from the cells when they are exposed to solar radiation.

The photovoltaic solar cells are typically formed with a plurality of light photovoltaic areas including photovoltaic elements such as photodiodes which are arranged as an array form over a semiconductor substrate. To improve conversion efficiency of the photovoltaic elements in the photovoltaic areas, a microlens array including a plurality of dome shaped microlenses are typically utilized to dispose over the photovoltaic areas and each of the microlenses substantially aligns to one of the photovoltaic elements in the photovoltaic area thereunder. Therefore, a fixed pitch is provided between a center of each of the microlens and a center of each of the photovoltaic areas. The dome shaped microlenses function as collectors to focus light from a larger area down to a smaller area of the photovoltaic areas for improving light collecting efficiency thereof.

Although light collecting efficiency can be improved by disposition of the dome shaped microlenses, light collecting accuracy of the photovoltaic elements, however, is not, since the photovoltaic elements in the photovoltaic areas are formed in an irregular pattern (from top view) rather a radially symmetrical pattern (from top view) due to line routing or other device design requirements, thereby showing different output currents of the photovoltaic elements at different locations.

### BRIEF SUMMARY OF THE INVENTION

Therefore, an improved solar cell module with optical components for improving light collection efficiency of photovoltaic elements therein is needed.

An exemplary embodiment of a solar cell module comprises a fixture with a solar cell wafer therein and a light-transmitting component formed in the fixture. The solar cell wafer comprises a semiconductor substrate with a plurality of photovoltaic elements formed thereon, wherein the photovoltaic elements are arranged in an array and a plurality of microlenses superimposed over a semiconductor substrate, respectively cover one of the photovoltaic regions, and a pitch between a center of the microlens and a center of the photovoltaic element thereunder increases from a center portion of the array of the photovoltaic elements toward an edge portion of the array of the photovoltaic elements. The light-transmitting component is opposite to the microlenses, wherein the light-transmitting component partially changes a direction of incident light collected from an ambient from not being perpendicular to a top surface of the microlenses.

Another exemplary embodiment of a solar cell module comprises a fixture with a solar cell wafer therein and a light-reflecting component with a planar surface physically connecting to the fixture. The solar cell wafer comprises a semiconductor substrate with a plurality of photovoltaic elements formed thereon, wherein the photovoltaic elements are arranged in an array and a plurality of microlenses superimposed over the semiconductor substrate, respectively cover one of the photovoltaic elements, wherein a pitch between a center of the microlens and a center of the array of the photovoltaic element thereunder increases from a first edge portion of the array of the photovoltaic elements toward a second edge portion of the array of the photovoltaic elements and the first edge portion is opposite to the second edge portion. The light-reflecting component with the planar surface changes incident light collected from an ambient from not being perpendicular to a top surface of the microlenses, wherein a top surface of the optical component and a top surface of the fixture incline at an angle less than 90 degrees.

Yet another exemplary embodiment of a solar cell module comprises a fixture with a solar cell wafer therein, a light-reflecting component with a concave surface and a connection member physically connecting to the light-reflecting component and the fixture. The solar cell wafer comprises a semiconductor substrate with a plurality of photovoltaic elements formed thereon, wherein the photovoltaic elements are arranged in an array and a plurality of microlenses superimposed over the semiconductor substrate, respectively cover one of the photovoltaic elements, wherein a pitch between a center of the microlens and a center of the photovoltaic element thereunder increases from a place rather than the center of the array of the photovoltaic elements toward an edge portion of the array of the photovoltaic elements. The light-reflecting component with the concave surface changes incident light collected from an ambient from not being perpendicular to a top surface of the microlenses. A top surface of the light-reflecting component and a top surface of the fixture incline at an adjustable angle less than 90 degrees.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic diagram of a solar cell module according to an embodiment of the invention;

FIG. 2 is a schematic top view showing a solar cell wafer of the solar cell module in FIG. 1, omitting a microlens array provided thereover;

FIGS. 3 and 5 are schematic top views respectively showing a solar cell wafer of the solar cell module in FIG. 1, having an symmetrical microlens array provided over the solar cell substrate therein, according to various embodiments of the invention;

FIG. 4 is a cross section taken along line 4-4 of FIG. 3;

FIG. 6 is a cross section taken along line 6-6 of FIG. 5;

FIG. 7 is a schematic diagram of a solar cell module according to another embodiment of the invention;

FIG. 8 is a schematic top view showing a solar cell wafer used in the solar cell modules in FIG. 7, having an asymmetrical microlens array according to an embodiment of the invention; and

FIG. 9 is a cross section taken along line 9-9 of FIG. 8.

FIG. 10 is a schematic diagram of a solar cell module according to yet another embodiment of the invention;

FIG. 11 is a schematic top view showing a solar cell wafer used in the solar cell modules in FIG. 10, having a partially symmetrical microlens array according to an embodiment of the invention; and

FIG. 12 is a cross section taken along line 12-12 of FIG. 11.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

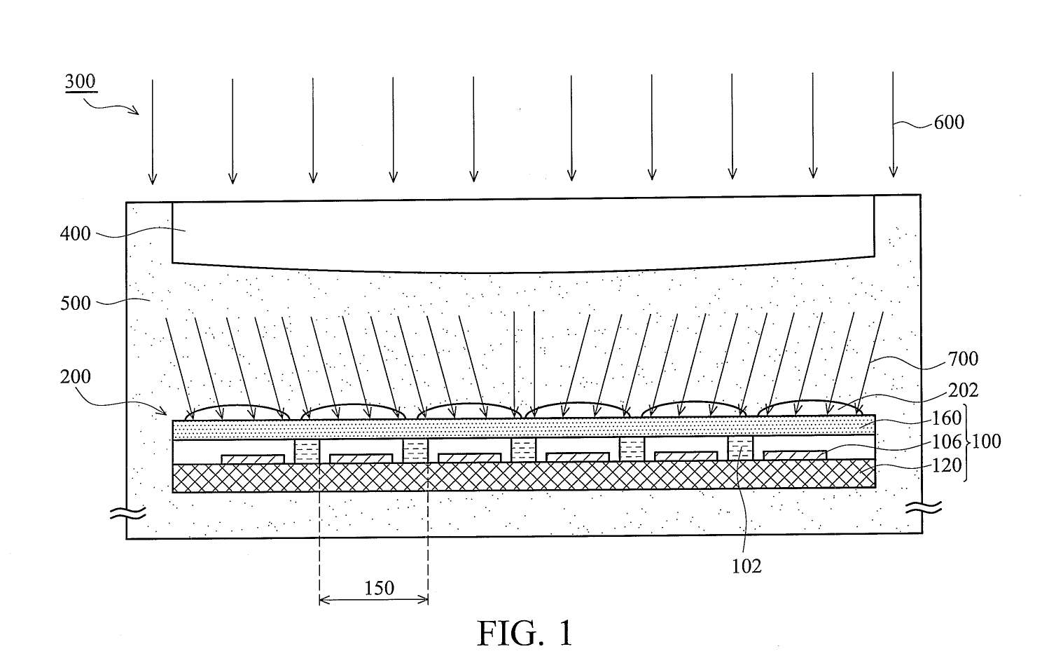

FIG. 1 is a schematic diagram showing a cross section of an exemplary solar cell module 300, including a fixture 500 with a solar cell wafer 200 and a light-transmitting component 400 formed therein. The solar cell wafer 200 is embedded within the fixture 500, including a semiconductor substrate 120 with a plurality of photovoltaic regions 150 formed thereon, each having a photovoltaic element 106 such as a photodiode and a conductive line 102 therein. A transparent layer 160 is provided over the semiconductor substrate 120 and a plurality of microlenses 202 are formed on the transparent layer 160. Each of the microlenses 202 substantially covers a photovoltaic region 150 thereunder.

As shown in FIG. 1, the light-transmitting component 400 is opposite to the microlenses 202 and is illustrated as an upside-down convex lens which partially changes a direction of incident light 600 from an ambient into transmitted light 700 partially having an incident direction not being perpendicular to a top surface of the microlenses 202 and the top surface of the transparent layer 160. The light-transmitting component 400 can be other lens such as planar convex lens or fresnel lens which are capable of changing a direction of incident light and focusing the transmitted light onto the microlenses 202 of the solar cell wafer 200. The light-transmitting component 400 is formed with a surface substantially the same or greater than a top surface of the solar cell wafer 200 to improve light collecting sensitivity and accuracy thereof. The solar cell wafer 200 is placed at a place in front of or behind a focal point of the light-transmitting component 400 for allowing more light to be collected by thereof. Preferably, the solar cell wafer 200 is placed at a place in front of the focal point of the light-transmitting component 400 to reduce a size of the solar cell module 300.

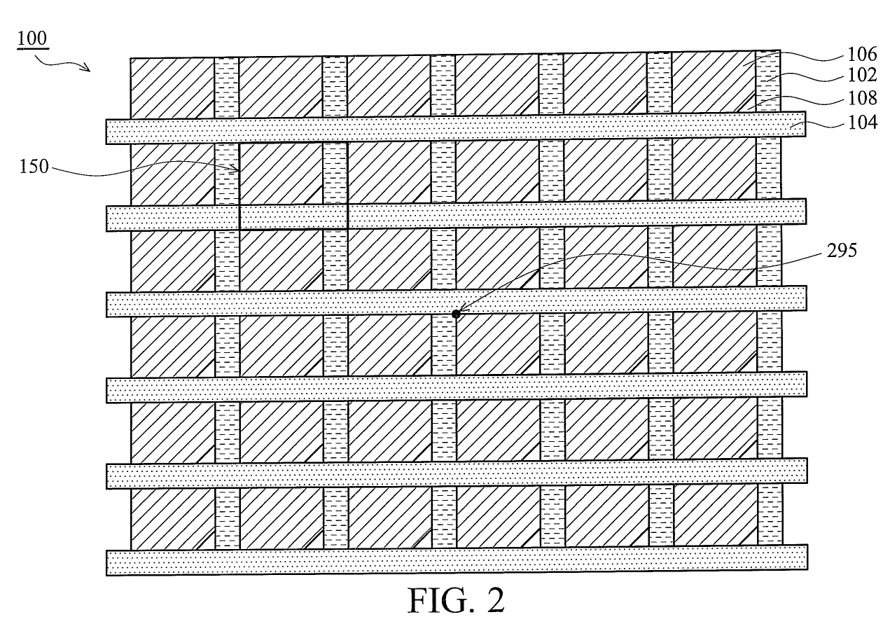

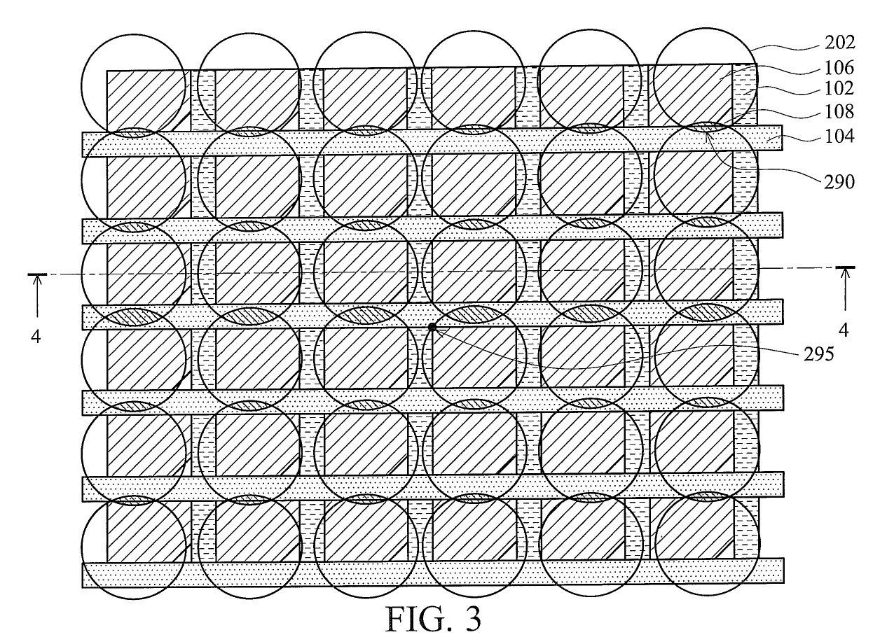

In this embodiment, a pitch between a center of the microlens 202 and a center of the photovoltaic region 150 thereunder substantially increases from a center 295 (see FIGS. 2 and 3) of the array of the photovoltaic regions 150 toward an edge portion of the array of the photovoltaic regions 150. The pitch between a center of the microlens 202 and a center of the photovoltaic region 150 thereunder at various places of photovoltaic regions 150 is determined by timing a focal length of the light-transmitting component 400 with tan θ (not shown), wherein θ is an incident angle of the transmitted light 700 to the top surface of the transparent layer 160.

Therefore, loss of light collecting sensitivity and accuracy of the photovoltaic elements 106 due to its irregular pattern (see FIG. 2) are thus compensated by shifting a position of the microlens 202 and disposition of the light-transmitting component 400 over the solar cell wafer 200. Overall light collecting sensitivity and accuracy of the solar cell module 300 are thus improved.

FIG. 2 shows a schematic top view of the solar cell wafer 200 of the solar cell module 300 in FIG. 1. The microlenses 202 of the solar cell wafer 200 are omitted and not shown in FIG. 2. The solar cell wafer 200 is illustrated as a 6×6 photovoltaic array 100 in FIG. 2 but is not limited thereto and a center 295 of this array is illustrated in FIG. 2. As shown in FIG. 2, the photovoltaic array 100 array includes a plurality of photovoltaic regions 150 formed over the semiconductor substrate 120 (see FIG. 1) which are arranged as an array. Each of the photovoltaic regions 150 are defined by a plurality of interacted conductive lines 102 and 104 and include a photovoltaic element 106 such as a photodiode therein. An additional element 108 is also formed in each of the photovoltaic regions 150 to function as a conductive element, for example, for connecting to the conductive line 104 or 108 with the photovoltaic element 106. Therefore, the photovoltaic element 106 in the photovoltaic regions 150 is formed with an irregular pattern and somehow affects overall light collecting sensitivity and accuracy of the solar cell wafer 200. Other elements, such as the interconnect elements or spacer elements can be further provided over the conductive lines 102 and/or 104 but are not illustrated here, for simplicity.

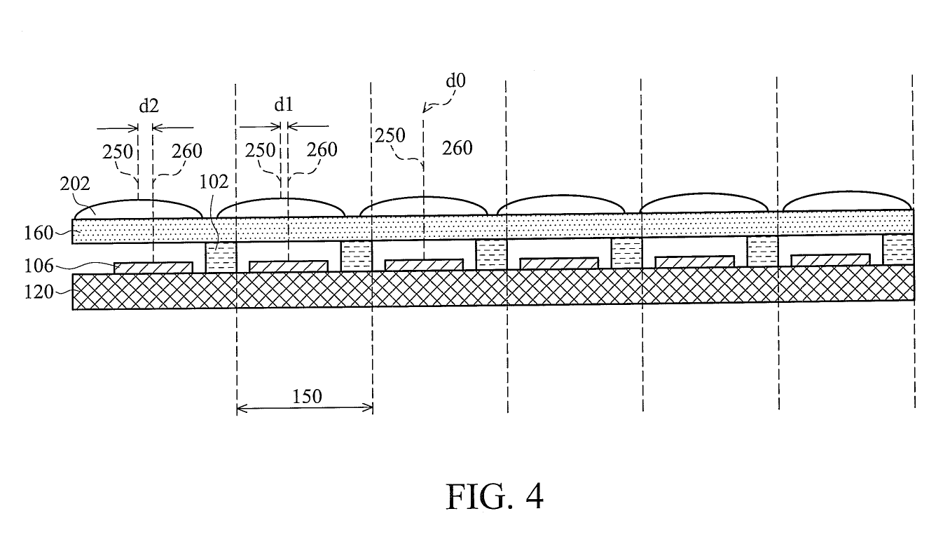

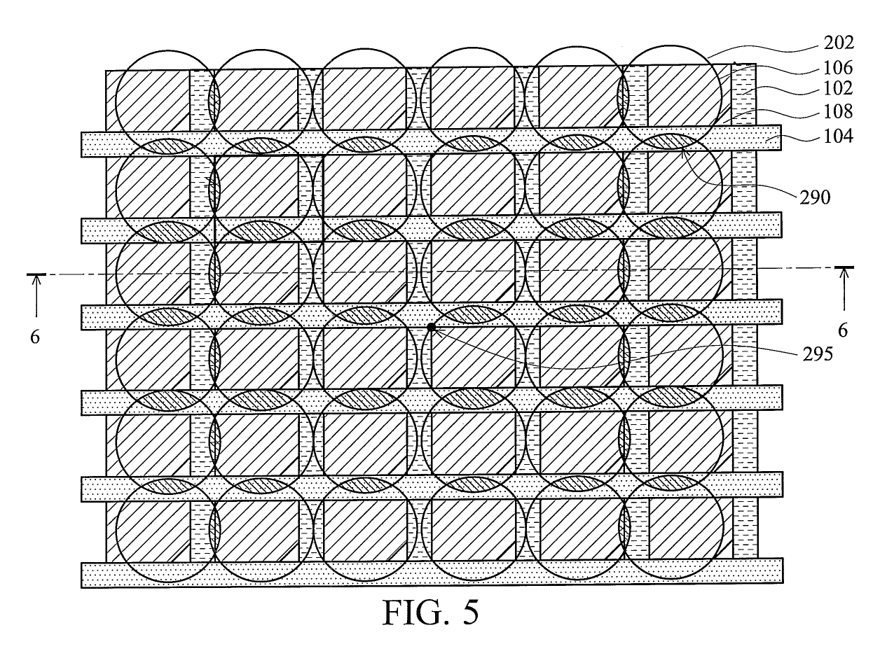

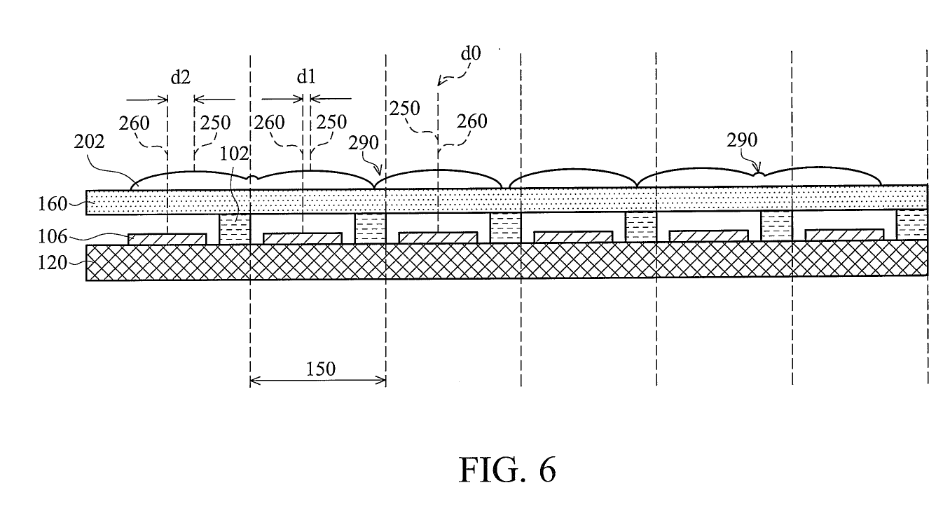

FIGS. 3-6 are schematic diagrams showing the solar cell wafer 200 of the solar cell module 300 in FIG. 1 having a symmetrical microlens array 202 provided thereover, wherein FIGS. 3 and 5 shows various top views and FIGS. 4 and 6 shows a cross section taken along line 4-4 of FIG. 3 and line 6-6 of FIG. 5, respectively.

As shown in FIGS. 3 and 4, a center of the microlens 202 shifts gradually toward an edge of the semiconductor substrate 120 thereunder and the microlenses 202 are symmetrically disposed over the semiconductor substrate 120 against a center 260 of the photovoltaic element 106 in the photovoltaic regions 150. Therefore, a pitch entitled as d2, d1 or d0 between a center 250 of the microlens 202 and a center 260 of the photovoltaic element 106 thereunder increases (i.e. d2>d1>d0) from a center portion of the array of the photovoltaic regions 150 (e.g the center two columns in FIG. 4) toward an edge of the array of the photovoltaic regions 150 (e.g the right or left two columns in FIG. 4).

As shown in FIGS. 5 and 6, a center 250 of the microlens 202 shifts gradually toward a center portion of the semiconductor substrate and the microlenses 202 are symmetrically disposed over the semiconductor substrate against a central region of the photovoltaic region 150. Therefore, a pitch entitled as d2, d1 or d0 between the center 250 of the microlens 202 and a center 206 the photovoltaic element 106 of the photovoltaic region 150 thereunder increases (i.e. d2>d1>d0) from a center portion of the photovoltaic regions 150 (e.g the center two columns in FIG. 6) toward an edge portion of the photovoltaic regions 150 (e.g the right or left two columns in FIG. 6).

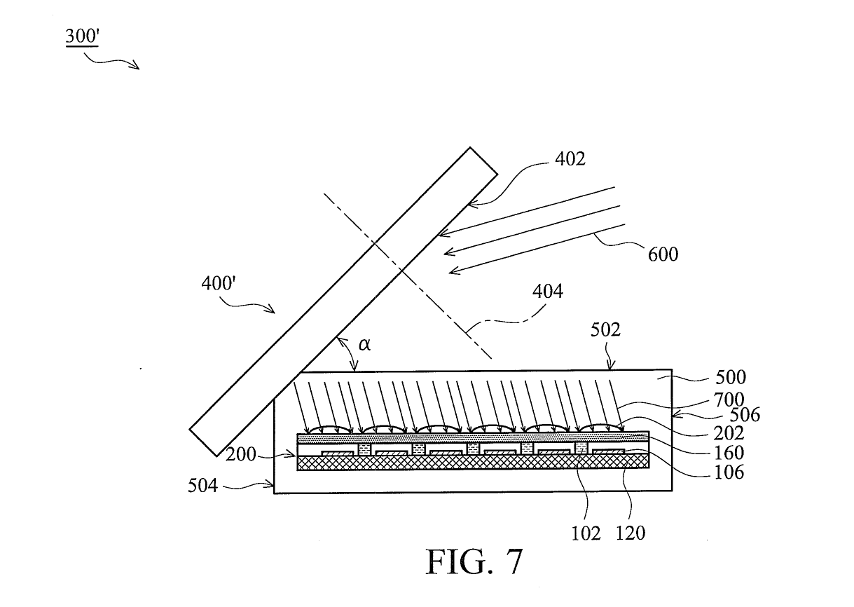

FIG. 7 is a schematic diagram showing a cross section of another exemplary solar cell module 300′, including a fixture 500 with a solar cell wafer 200 formed therein. In addition, a light-reflecting component 400′ is physically connected with the fixture 500 from an edge thereof by connection members (not shown). An additional fixture (not shown) can be further provided to connect the light-reflecting component 400′ with an opposing edge of the fixture 500, thereby fixing thereof. As shown in FIG. 7, the light-reflecting component 400′ is illustrated as a reflector with a planar surface. In this embodiment, the solar cell wafer 200 is embedded within the fixture 500, including elements which are the same as that shown in FIG. 1 and are not described here again.

As shown in FIG. 7, an angle α less than 90 degrees is inclined between a reflective surface 402 of the light-reflecting component 400 and a top surface 502 of the fixture 500. Therefore, incident light 600 first arrives at the reflective surface 402 and is then reflected along a direction (not shown) against an optical axis 404 of the light-reflecting component 400, thereby forming transmitted light 700 passing through the fixture 500 and arriving at the microlenses 202 therein. The transmitted light 700 is then collected by the microlenses 202 along an incident direction not being perpendicular to a top surface of the microlenses 202.

The light-reflecting component 400′ in FIG. 7 is formed with a surface substantially the same or greater than a top surface of the solar cell wafer 200 to improve light collecting sensitivity and accuracy of the solar cell module 300′. The solar cell wafer 200 is placed at a place in front of or behind a focal point of the light-transmitting component 400 to increase amounts of light to be collected by thereof. Preferably, the solar cell wafer 200 is placed at a place in front of the focal point of the light-reflecting component 400 to reduce a size of the solar cell module 300′.

In the embodiments illustrated in FIG. 7, a pitch between a center of the microlens 202 and a center of the photovoltaic region 106 thereunder increases from a first edge portion of the photovoltaic regions in the fixture 500 near a left side 504 thereof toward of the photovoltaic regions of the second edge portion of the photovoltaic regions 106 in the fixture 500 near a right side 506 thereof. The first edge portion is opposite to the second edge portion. The pitch between a center of the microlens 202 and a center of the photovoltaic region 150 thereunder at various places of the photovoltaic regions 150 is determined by an incident angle of the transmitted light 700 between a top surface of the transparent layer 160 (or the microlens 202) and is determined by timing an incident angle of the transmitted light 700 with a focal length of the light-transmitting component 400.

Therefore, loss of light collecting sensitivity and accuracy of the photovoltaic elements 106 due to its irregular pattern (see FIG. 2) are thus compensated by shifting a position of the microlens 202 thereover and disposition of the light-reflecting component 400 over the solar cell wafer 200. Overall light collecting sensitivity and accuracy of the solar cell module 300 is thus improved.

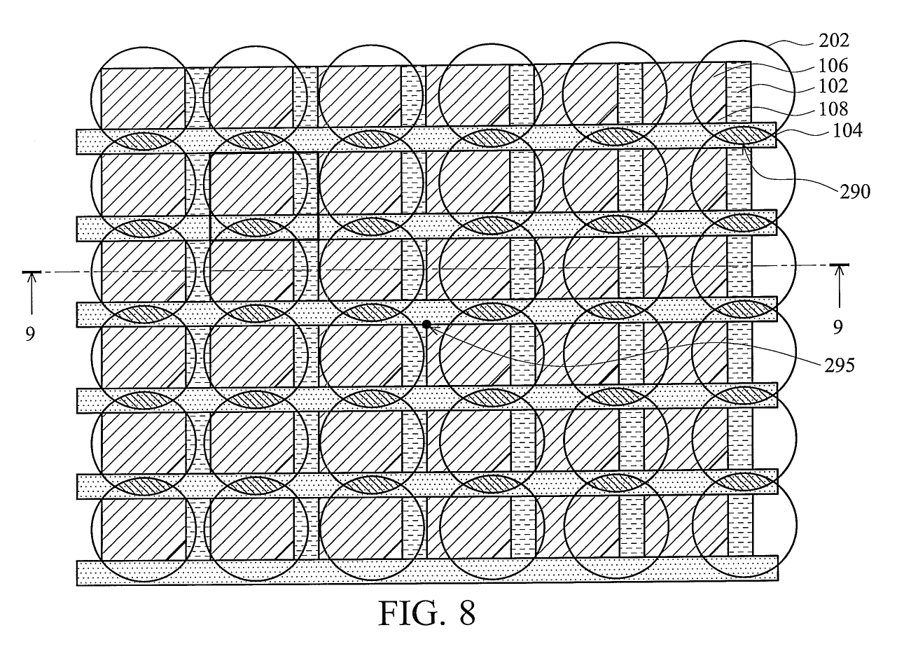

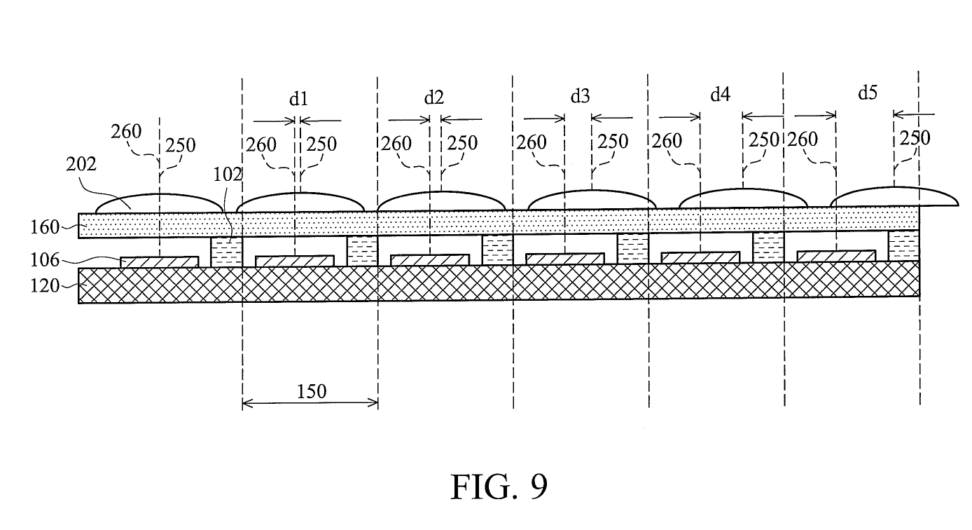

FIGS. 8 and 9 are schematic diagrams respectively showing a solar cell wafer used in the solar cell modules in FIG. 7, having an asymmetrically microlens array provided over the semiconductor substrate. FIG. 8 illustrates a schematic top view and FIG. 9 illustrates a cross section taken along line 9-9 of FIG. 8. As shown in FIGS. 8 and 9, a center 250 of the microlens 202 shifts gradually from a first edge portion of the microlenses array toward a second edge portion of the microlenses array opposite thereto and the microlenses 202 are thus asymmetrically disposed over the semiconductor substrate against a center portion 260 of the photovoltaic element 106 in the photovoltaic regions 150. Therefore, a pitch entitled as d5, d4, d3, d2, or d1 between the center 250 of the microlens 202 and a center portion 260 of the photovoltaic element 106 of the photovoltaic region thereunder increases (i.e. d5>d4>d3>d2>d1) from a first edge portion of the photovoltaic regions (e.g the leftist center two columns in FIG. 9) toward a second edge portion of the photovoltaic regions (e.g the right or left two columns in FIG. 9) opposite to the first edge portion.

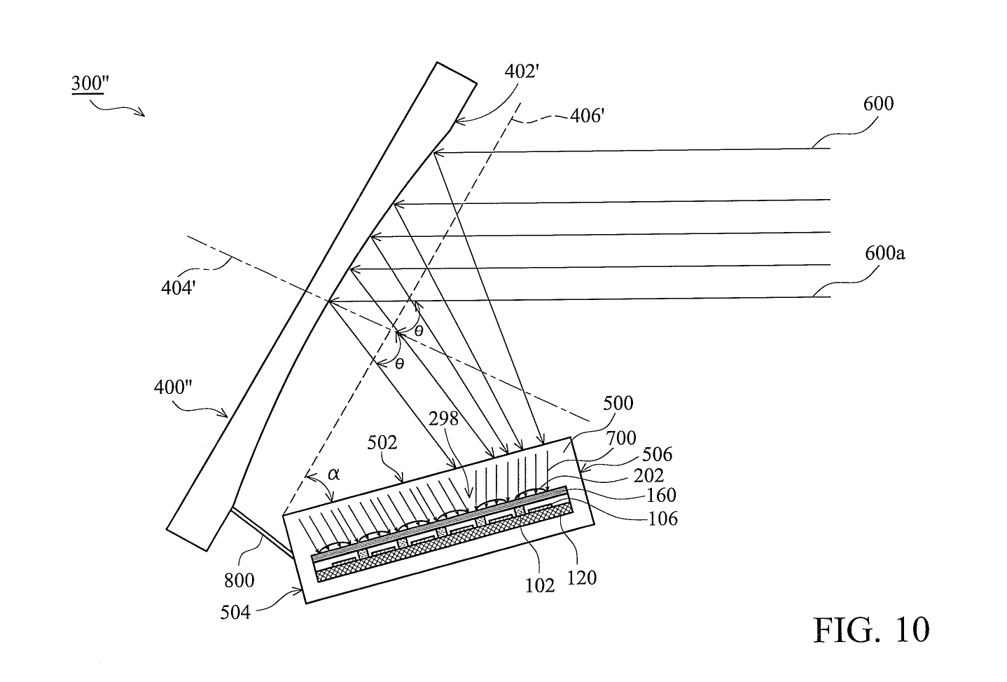

FIG. 10 is a schematic diagram of a solar cell module 300″ modified from that illustrated in FIG. 7. As shown in FIG. 10, the solar cell module 300″ includes a fixture 500 with a solar cell wafer 200 formed therein. In addition, a light-reflecting component 400″ which is structurally independent from the fixture 500 is structurally connected with the fixture 500 by a connection member 800. An additional fixture (not shown) can be further provided to connect the light-reflecting component 400″ with an opposing edge of the fixture 500, thereby fixing thereof. As shown in FIG. 10, the light-reflecting component 400″ is illustrated as a reflector with a concave surface 402′. However, the light-reflecting component 400″ can be, for example, an array of reflector, or a MEMs reflector array and is not limited by the above illustrated reflector.

As shown in FIG. 10, an angle α less than 90 degrees is inclined between a hypothesis plane surface 406′ of the light-reflecting component 400′ and a top surface 502 of the fixture 500. The hypothesis plane surface 406′ is parallel to a backside surface of the light-reflecting component 400′. Therefore, incident light 600 first arrives at the reflective surface 402′ and is then reflected along a direction (not shown) against an optical axis 404′ of the light-reflecting component 400, thereby forming transmitted light 700 passing through the fixture 500 and arriving at the microlenses 202 therein. The transmitted light 700 are collected by the microlenses 202 in an incident direction not being perpendicular to a top surface of the microlenses 202. In this embodiment, the solar cell wafer 200 is embedded within the fixture 500, including elements which are similar with that shown in FIG. 1 and are not described here again. Elements and positions therein are similar with those illustrated in the embodiment illustrated in FIG. 7 and thus are not described here again, for brevity.

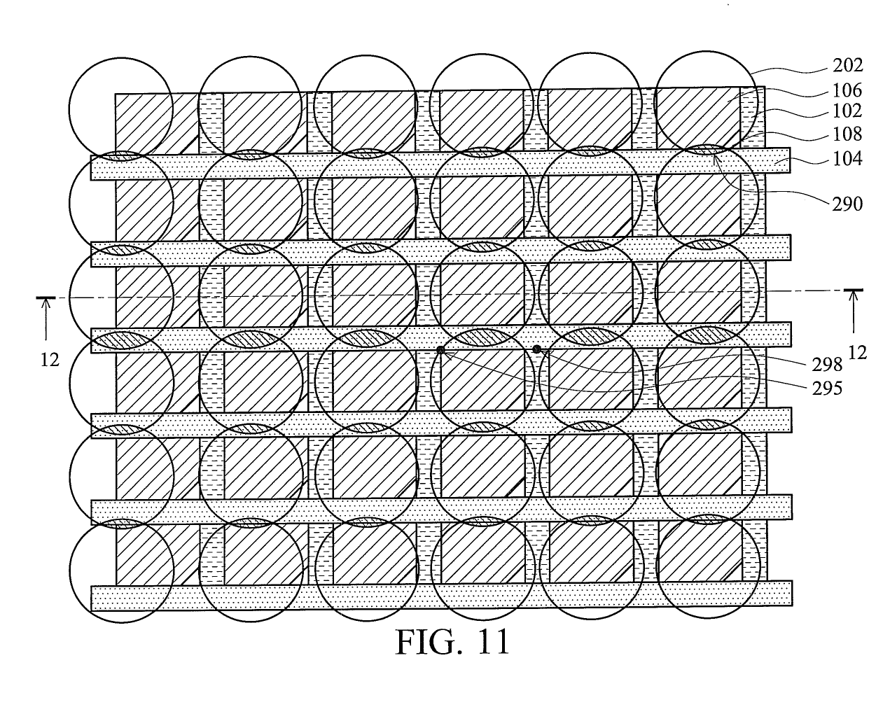

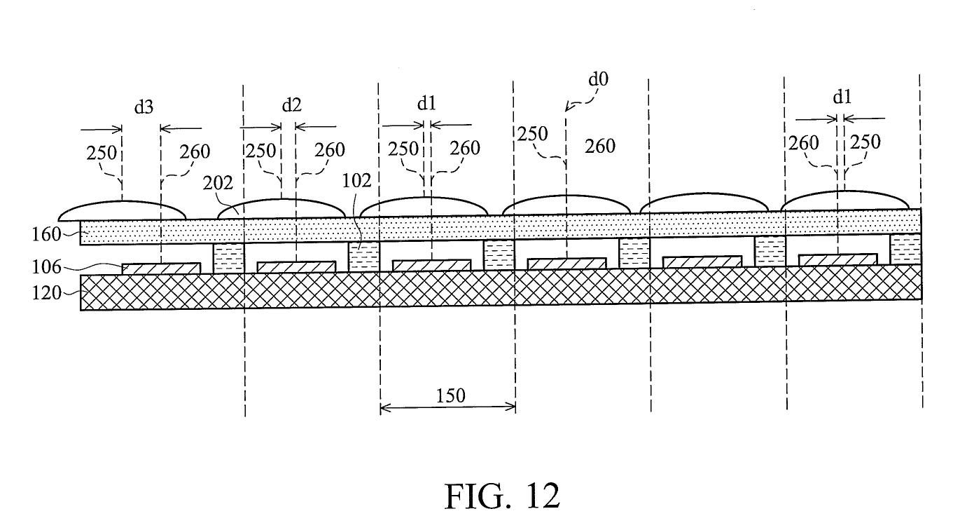

FIGS. 11 and 12 are schematic diagrams showing the solar cell wafer 200 of the solar cell module 300″ in FIG. 10 having a partially symmetrical microlens array 202 provided thereover, wherein FIGS. 11 shows a top view and FIG. 12 shows a cross section taken along line 12-12 of FIG. 11.

As shown in FIGS. 11 and 12, a center of the microlens 202 shifts gradually toward an edge of the semiconductor substrate 120 thereunder from a place 298 near the center 295 of the array of the array of the photovoltaic regions 150 and the microlenses 202 are partially symmetrically disposed over the semiconductor substrate 120 against a place 298 of the photovoltaic element 106 in the photovoltaic regions 150. The place 298 is substantially aligned with an reflected light 600b obtained from an incident light 600a reflected along the optical axis 404′, having an angle θ of about 10-80 degrees defined between the optical axis 404′ of the light-reflecting component 400″ and the incident light 600a and the reflected light 600b. Therefore, a pitch entitled as d3, d2, d1 or d0 between a center 250 of the microlens 202 and a center 260 of the photovoltaic element 106 thereunder increases (i.e. d3>d2>d1>d0) from a place 298 rather than a center 295 of the array of the photovoltaic regions 150 toward an edge of the array of the photovoltaic regions 150. The photovoltaic regions 150 having no displacement between the center of the photovoltaic regions 150 and the microlenses 202 thereabove are substantially located at an area aligned to the optical axis 404′ and are illustrated as, for example, an area comprising the photovoltaic regions 150 at intersections between the 2^{nd} and 3^{rd} columns (from the right side of the array) and the 2^{nd} and 3^{rd} rows (from the upper side of the array) of the photovoltaic regions 150.

Arrangement of the partially symmetrical microlens array 202 illustrated in FIGS. 11 and 12 can be provided with a center 250 of the microlens 202 shifts gradually toward a center portion of the semiconductor substrate and the microlenses 202 are partially symmetrically disposed over the semiconductor substrate against a central region of the photovoltaic region 150, as that illustrated in FIGS. 5 and 6, and are not illustrated here, for simplicity. Therefore, a pitch entitled as d2, d1 or d0 between the center 250 of the microlens 202 and a center 206 the photovoltaic element 106 of the photovoltaic region 150 thereunder increases (i.e. d3>d2>d1>d0) from a place 298 next to a center 295 of the array of the photovoltaic regions 150 toward an edge of the array of the photovoltaic regions 150.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell module, comprising:
a fixture with a solar cell wafer therein, wherein the solar cell wafer comprises:
a semiconductor substrate with a plurality of photovoltaic elements formed thereon, wherein the photovoltaic elements are arranged in an array; and
a plurality of microlenses superimposed over the semiconductor substrate, respectively covering one of the photovoltaic elements, wherein a pitch between a center of the microlens and a center of the photovoltaic element thereunder increases from a center portion of the array of the photovoltaic elements toward an edge portion of the array of the photovoltaic elements;
and
a light-transmitting component formed in the fixture, opposing the microlenses, wherein the light-transmitting component partially changes a direction of incident light collected from an ambient from not being perpendicular to a top surface of the microlenses.

2. The solar cell module as claimed in claim 1, wherein the transmitting component is convex lens, planar convex lens or fresnel lens.

3. The solar cell module as claimed in claim 1, wherein a center of the microlens shifts gradually toward an edge of the semiconductor substrate and the microlenses are symmetrically disposed over the semiconductor substrate against a center portion of the photovoltaic regions.

4. The solar cell module as claimed in claim 1, wherein a center of the microlens shifts gradually toward a center of the semiconductor substrate and the microlenses are symmetrically disposed over the semiconductor substrate against a central region of the photovoltaic region.

5. The solar cell module as claimed in claim 1, wherein the light-transmitting component is formed with a surface substantially greater than a top surface of the solar cell wafer.

6. The solar cell module as claimed in claim 1, wherein the solar cell wafer is positioned at a place in front of or behind a focus of the light-transmitting component.

7. The solar cell module as claimed in claim 1, wherein the pitch between the center of the microlens and the center of the photovoltaic region thereunder equals to a focal length of the microlens times an angle of the light incident to the microlens.

8. A solar cell module, comprising:
a fixture with a solar cell wafer therein, wherein the solar cell wafer comprises:
a semiconductor substrate with a plurality of photovoltaic elements formed thereon, wherein the photovoltaic elements are arranged in an array; and
a plurality of microlenses superimposed over the semiconductor substrate, respectively covering one of the photovoltaic elements, wherein a pitch between a center of the microlens and a center of the photovoltaic element thereunder increases from a first edge portion of the array of the photovoltaic elements toward a second edge portion of the array of the photovoltaic elements and the first edge portion is opposite to the second edge portion;
and
a light-reflecting component with a planar surface physically connecting to the fixture for changing incident light collected from an ambient from not being perpendicular to a top surface of the microlenses, wherein a top surface of the optical component and a top surface of the fixture incline at an angle less than 90 degrees.

9. The solar cell module as claimed in claim 8, wherein the microlenses are asymmetrically disposed over the semiconductor substrate against a center portion of the array of the photovoltaic elements.

10. The solar cell module as claimed in claim 8, wherein the light-reflecting component is formed with a planar surface substantially greater than a top surface of the solar cell wafer.

11. A solar cell module, comprising:
a fixture with a solar cell wafer therein, wherein the solar cell wafer comprises:
a semiconductor substrate with a plurality of photovoltaic elements formed thereon, wherein the photovoltaic elements are arranged in an array; and
a plurality of microlenses superimposed over the semiconductor substrate, respectively cover one of the photovoltaic elements, wherein a pitch between a center of the microlens and a center of the photovoltaic element thereunder increases from a place rather than the center of the array of the photovoltaic elements toward an edge portion of the array of the photovoltaic elements;
a light-reflecting component with a concave surface for changing incident light collected from an ambient from not being perpendicular to a top surface of the microlenses; and
a connection member physically connected to the light-reflecting component and the fixture, wherein a top surface of the light-reflecting component and a top surface of the fixture incline at an adjustable angle less than 90 degrees.

12. The solar cell module as claimed in claim 11, wherein the microlenses are partially symmetrically disposed over the semiconductor substrate against a place rather than a center of the array of the photovoltaic elements.

13. The solar cell module as claimed in claim 11, wherein the light-reflecting component is formed with a planar surface substantially greater than a top surface of the solar cell wafer.

14. The solar cell module as claimed in claim 11, wherein the microlenses are partially symmetrically disposed over the semiconductor substrate against a place rather than a center of the array of the photovoltaic elements and a center of the microlens shifts gradually toward an edge of the semiconductor substrate from the place.

15. The solar cell module as claimed in claim 11, wherein and the microlenses are symmetrically disposed over the semiconductor substrate against a place rather rather than a center of the array of the photovoltaic elements and a center of the microlens shifts gradually toward a center of the semiconductor substrate from the place.

16. The solar cell module as claimed in claim 11, wherein the light-reflecting component is a reflector with a concave surface, an array of reflector, or a MEMs reflector array.
